(19) United States
(12) Patent Application Publication
(10) Pub. No.: US 2020/0156168 A1
(43) Pub. Date: May 21, 2020

(54) Soldering Device, Soldering System And Method

(71) Applicant: ERSA GmbH, Wertheim (DE)

(72) Inventors: Meinrad Eckert, Freudenberg (DE); Stefan Voelker, Hafenlohr (DE)

(73) Assignee: ERSA GmbH, Wertheim (DE)

(21) Appl. No.: 16/630,145

(22) PCT Filed: Jul. 2, 2018
(86) PCT No.: PCT/EP2018/067749

§ 371 Date: Jan. 10, 2020

(30) Foreign Application Priority Data
Jul. 11, 2017 (DE) 10 2017 115 548.1

(51) Int. Cl. B23K 1/018; B23K 1/08; B08B 1/04; H05K 3/26

(52) U.S. Cl. CPC B23K 1/018; B23K 1/085; H05K 2203/0257; H05K 3/26; B08B 1/04

(57) ABSTRACT

The invention relates to a soldering device for removing solder pearls and/or solder balls from the lower face of a printed circuit board, in particular a soldering device for a soldering system for a selective wave soldering process, comprising a brush device for removing solder pearls and/or solder balls from the lower face of a printed circuit board. The brush device has a brush which can be driven about a drive axis and which is designed to remove the solder pearls and/or solder balls, wherein a moving device is provided, said brush device being arranged on the moving device such that the brush device can be moved relative to the printed circuit board in the direction of an X, Y, and Z axis.

### BACKGROUND

The invention relates to a soldering device for removing solder pearls and/or solder balls from an underside of a circuit board, particularly a soldering device for a soldering system for a selective wave soldering process, with a brush device for removing solder pearls and/or solder balls from the underside of the circuit board, wherein the brush device has a brush that can be driven about a drive axis, which is configured for removing solder pearls and/or solder balls.

When soldering components, particularly when soldering connector strips and other similar components, which are inserted through a circuit board and are soldered to the underside of the circuit board, can retain small solder pearls or solder balls stuck to the underside of the circuit board, which can lead to failures over the life of the circuit board, for example if the solder pearls or solder balls detach over time. Short circuits can occur due to detached solder pearls or solder balls, which can lead to a failure of the electronic components.

The removal of solder pearls or solder balls from the underside of the circuit board is therefore desirable. Devices of the type previously mentioned are thus known from the prior art. In these, solder pearls respectively solder balls are removed from the underside of a circuit board with a rotating cylindrical brush having bristles on its lateral surface, while the circuit board is conveyed in the processing direction through a system, for example through a soldering system for a selective wave soldering process, so that the circuit board is moved relative to the fixed brush roller. With brush rollers of this type, however, no targeted removal of solder pearls and solder balls is possible, as the entire underside of the circuit board comes into contact with the lateral surface of the brush roller, so that the entire underside of the circuit board is brushed off.

Furthermore, it is known from the prior art to remove solder pearls and solder balls on a circuit board only at the locations where soldering has occurred. In this case, the components are brushed off along the soldered paths on the underside of the circuit board with a manual brush. In this case, the use of the brush occurs only in soldered areas, so that the entire underside of the circuit board need not be brushed off. It has however proven disadvantageous, with this manual brushing, that the underside to be brushed off must be set facing a worker for the brushing step, so that the entire circuit board must be rotated by 180°. In this case it cannot be excluded that solder pearls or solder balls brushed off or removed can remain in cracks and crevices of the components, respectively in cracks and crevices between the components and the circuit board. Such solder pearls and solder balls remaining in cracks and crevices can also lead to failures, during the life of the circuit board, for example if the solder pearls or solder balls detach over time. Short circuits can occur due to detached solder pearls or solder balls, which can lead to a failure of the electronic components.

### SUMMARY OF THE INVENTION

The invention therefore has as its object to provide a facility which allows an easy, safe and automated removal of solder pearls and/or solder balls from the underside of a circuit board.

This object is achieved by a soldering device with the features of claim 1. A soldering device of this type is characterized in that a movement device is provided, wherein the brush device is so arranged on the movement device that it can be moved, automatically in particular, relative to the circuit board in the direction of an X, Y and Z axis. By X, Y and Z axis is meant the axes of a system of axes, such as are customarily implemented in machine tools, in which all axes are arranged orthogonally to one another. Advantageously, the X and Y axes are arranged parallel to the circuit board, so that a movement of the brush device in the X-Y plane spanned by the X and Y axes leads to a shifting of the brush device relative to the circuit board, whereby a separation in the direction of the Z axis remains unchanged in the process. This separation in the direction of the Z axis can then be altered by a movement of the brush device in the direction of the Z axis.

In accordance with an advantageous further development of the soldering device, it is provided that the movement device is a portal system.

In this case it is conceivable that the portal system has at least one X-axis drive, which is configured for moving the brush device along the X axis, wherein the portal system has at least one Y-axis drive, which is configured for moving the brush device along the Y axis, and wherein the portal system has at least one Z-axis drive, which is configured to move the brush device along the Z axis. In this case it is conceivable for example that the axis drives are arranged so as to move over one another, so that a movement of the Y-axis drive leads to a shift in the X-axis drive and of the Z-axis drive positioned on the X-axis drive in the direction of the Y axis, wherein a movement of the X-axis drive leads to a shift of the Z-axis drive positioned on the X-axis drive in the direction of the Z axis.

Advantageously, the axis drives are configured as linear drives, particularly as chain drives, screw drives, ball screw drives, direct linear drives, hydraulic cylinders and/or pneumatic cylinders.

According to an additional advantageous configuration of the soldering device, it is provided that the movement device is the manipulator of a robot. In this case it is conceivable that the brush device is arranged at a free end of a robot arm of an industrial robot.

An additional, particularly advantageous configuration of the soldering device is characterized in that the brush device has a brush drive, which is configured to generate an oscillating rotating motion of the brush. The generation of an oscillating rotating motion has proven especially effective for the removal of solder pearls and/or solder balls from the underside of the circuit board. In this case it is conceivable that the brush drive is configured as an electrical or pneumatic drive. The drive is advantageously so configured that the brush carries out oscillating rotating motions with a frequency of approximately 50 Hz to approximately 400 Hz, preferably with a frequency of approximately 250 Hz. According to a particularly advantageous further development, the drive is so configured that it carries out 14,000 oscillating movements per minute with a voltage of 24 volts (this corresponds to approximately 230 Hz), wherein the oscillation speed can be adjusted by controlling the voltage between 0 and 24 volts. It is also conceivable, however, that the drive does not drive the brushes in an oscillation manner, but rather staggers the rotating motion in the clockwise direction or in the opposite direction.

In order to be able to prevent destruction of the electronic components positioned on the circuit board to be processed, it has proven advantageous for the brush device to be configured to drain off electrostatic discharges. Thus the electrostatic discharges occurring on the brush device can be drained, without this leading to the destruction of components due to the electrostatic discharges.

It is particularly preferred in this case if the brush has electrically conducting bristles. In this case it is conceivable that the bristles are made from a so-called ESD (electrostatic discharge) plastic. It is also conceivable, however, that the brushes include bristles made of electrically conducting carbon.

In order to be able to allow safe drainage of electrostatic discharges, it has proven advantageous if the brushes are electrically connected to a ground connection of the soldering device.

According to another advantageous configuration of the soldering device it is provided, that the brushes have a brush surface arranged orthogonally to the drive axis, wherein the brush surface is circular or ring-shaped. It is advantageous to configure the brushes cylindrically, e.g. the bristles of the brushes extend cylindrically in the direction of the drive axis. In order to be able to allow reliable removal of solder pearls and/or solder balls on the underside of the circuit board even with small structures it has proven advantageous if the brushes have a brush diameter in the range of approximately 1 mm to approximately 40 mm, preferably in the range of approximately 6 mm to approximately 20 mm.

It is also advantageous if an angle adjustment device is provided, which is configured for adjusting a processing angle of the brush device in the range of approximately 0° to approximately 20° to the Z axis. A processing angle is understood in this case to mean an angle between the drive axis of the brush device and the Z axis of the movement device. By adjusting the processing angle, the brush surface can be positioned, depending on spatial restrictions on the underside of the circuit board relative to the circuit board, respectively to the contact pins inserted through the circuit board, so as to be able to allow a particularly reliable removal of solder pearls and/or solder balls.

In order to allow automated adjustment of the processing angle, it is conceivable that the angle adjusting device includes at least one electrical adjustment motor. It is however also conceivable that the angle adjustment occurs manually.

An additional advantageous configuration of the soldering device provides that a collecting bin is provided, which is configured to collect solder pearls and/or solder balls removed from the underside of the circuit board. Advantageously, the collecting bin is configured bowl-shaped and arranged concentric with the drive axis of the brush device. Thus the solder pearls and/or solder balls removed by means of the brush device can be prevented from flying around through the use of the collecting bin. Furthermore, it can also be prevented that removed solder pearls and/or solder balls lead to contamination, for example in the operating area of a soldering system for a selective wave soldering process. In order to be able to prevent expulsion of already collected solder pearls and/or solder balls, it is conceivable that the collecting bin is not motion-coupled with the brushes.

In this case it is particularly preferred if a suction device is provided, which is configured to generate a reduced pressure in the collecting bin. Thus removed solder pearls and/or solder balls can be sucked away by the use of the suction device and thus be surely collected by means of the collection bin.

The previously mentioned task is further achieved by a soldering system for a selective wave soldering process, including a soldering device according to at least one of claims 1 to 14.

Furthermore, the previously mentioned task is achieved by a method for removing solder pearls and/or solder balls from an underside of a circuit board, particularly by a method for operating a soldering system according to claim 15, wherein solder pearls and/or solder balls are removed from the underside of the circuit board with a brush which carries out an oscillating rotating movement, wherein the brush moves relative to the circuit board in the direction of the X, Y and/or Z axes.

### BRIEF DESCRIPTION OF THE DRAWINGS

Additional details and advantageous additional developments can be derived from the following description, by reference to which an embodiment of the invention is described in more detail.

They show:

FIG. 1 a schematic side view of a brush device of a soldering device according to the invention for removing solder pearls and/or solder balls from an underside of a circuit board; and

FIG. 2 a schematic side view of a soldering device according to the invention for removing solder pearls and/or solder balls from an underside of a circuit board.

### DETAILED DESCRIPTION

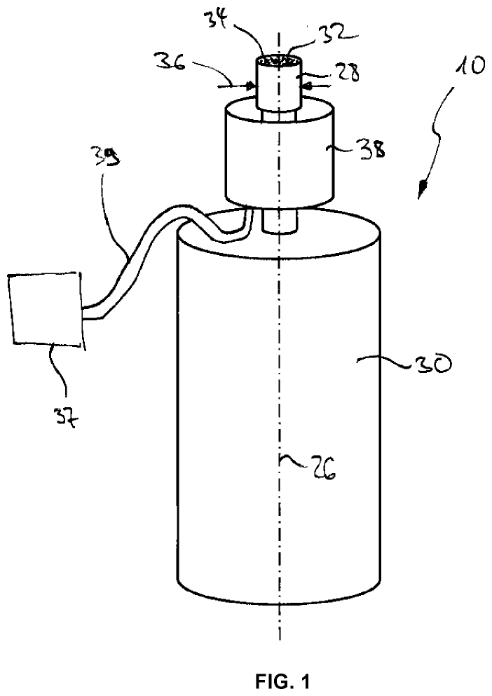

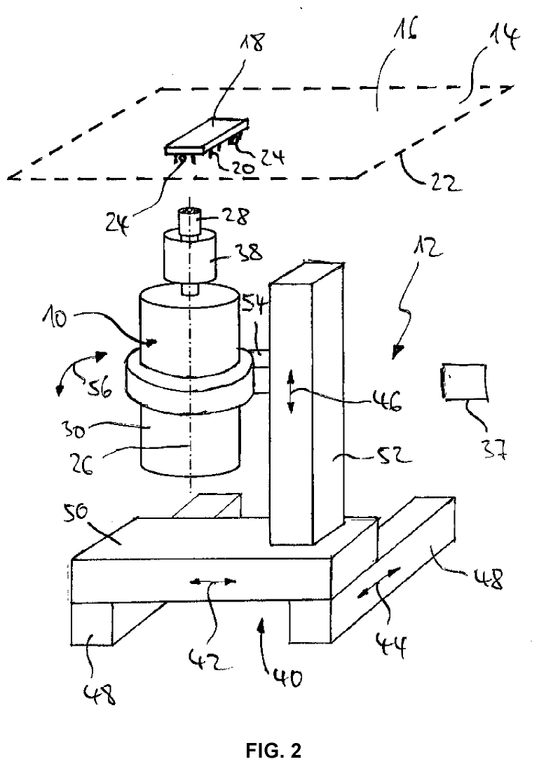

FIG. 1 shows a brush device 10 of a soldering device 12 shown in FIG. 2 for removing solder pearls and/or solder balls from an underside of a circuit board 14 shown in FIG. 2 in schematic side view. FIG. 2 shows a schematic side view of the soldering device 12 according to the invention. In FIG. 2 the circuit board 14, through which is inserted, from an upper side 16, an electronic component 18 with its contact pins 20 and is soldered from an underside 22 of the circuit board 14 to it, for example by selective wave soldering, is shown above the soldering device 12, in a soldering system for a selective wave soldering process not shown in the figures.

On the underside 22 of the circuit board 14, small solder pearls and/or solder balls 24, which were generated by a solder wave during selective wave soldering, are adhering in the area of the contact pins 20. These so-called solder pearls and/or solder balls 24 are undesirable and can lead to failure of the circuit board 14, respectively of the component 18, during the life of the circuit board 14, if they detach over time. Detached solder pearls and/or solder balls 24 can lead to short circuits, which can lead to destruction of an electronic component 18.

The soldering device 12 is configured overall for the removal of solder pearls and/or solder balls 24 from the underside 22 of the circuit board 14 and can in particular be configured to be built into a soldering system, not shown, for a selective wave soldering process.

The soldering device 12 has the brush device 10 shown in FIG. 1. In turn, the brush device 10 has a brush 28 that can be driven around a drive axis 26, which is configured for removing solder pearls and/or solder balls 24.

The brush device 10 has a brush drive 30, which is configured to generate an oscillating rotating movement of the brushes 28 around the drive axis 26. The brush drive 30 is configured as an electric drive wherein, in operation, the brushes 28 carry out oscillating rotating movements with a frequency of approximately 50 Hz to approximately 400 Hz, preferably with a frequency of approximately 250 Hz. Advantageously, the brush drive 30 is so configured that it carries out 14,000 oscillating movements per minute with a voltage of 24 volts (this corresponds to approximately 230 Hz), wherein the oscillation speed can be adjusted by controlling the voltage between 0 and 24 volts.

The brush 28 has a brush surface 32 arranged orthogonally to the drive axis 26, which is configured circularly (see FIG. 1). The brush 28 is cylindrical, i.e. the bristles 34 of the brush 28 extend cylindrically in the direction of the drive axis 26. In FIGS. 1 and 2, the bristles 34 are shown only schematically. The brush 28 has a brush diameter 36 in the range of approximately 1 mm to approximately 40 mm, preferably in the range of approximately 6 mm to approximately 20 mm, so that even with small structures and cramped conditions on the underside of 22 of the circuit board 14, reliable removal of solder pearls and/or solder balls 24 can be allowed.

In order to be able to avoid destruction of the electronic components 18 arranged on the circuit board 14 to be processed, the brush device 10 is configured for draining electrostatic discharges. Thus electrostatic discharges that occur can be drained through the brush device 10, without resulting in the destruction of components 18 due to electrostatic discharges.

In this case the brush 28 has electrically conducting bristles 34, which are made from a so-called ESD (electrostatic discharge) plastic or from electrically conducting carbon, or at least include it. The brush 28, respectively their bristles 34, are electrically connected in this case to a ground connection of the soldering device 12, respectively a ground connection of a soldering system not shown in the figures for a selective wave soldering process.

A collecting bin 38 is provided concentric with the drive axis 26, which is configured to collect the solder pearls and/or solder balls 24 removed from the underside 22 of the circuit board 14. The collecting bin 38 is bowl-shaped and surrounds the brush 28 in the circumferential direction, i.e. orthogonal to the drive axis 26, at least in part, so that the flying around of the solder pearls and/or solder balls 24 removed by the brush device 10 can be prevented by the use of the collecting bin 38. Furthermore, contamination, for example in the operating area of a soldering system for a selective wave soldering process, by removed solder pearls and/or solder balls 24, can also be prevented. In order to be able to prevent expulsion of solder pearls and/or solder balls 24 already collected, it is also conceivable that the collecting bin 38 is not movement-coupled with the brush 28. In this case it is conceivable that the collecting bin 38 is arranged on a hollow shaft which is connected with the drive 30, wherein the brush 28-driving drive shaft is carried through the hollow shaft.

It is conceivable that a suction device 37 is provided, which is configured for generating a reduced pressure in the collecting bin 38. The suction device 37 can for example, in this case, include a vacuum pump and be connected with the collecting bin 38 by means of a hose 39. Thus removed solder pearls and/or solder balls 24 can be sucked away by the use of the suction device 37 and thus be safely collected by the collecting bin 38.

As can be ascertained in FIG. 2, the brush device 10 is so arranged, on a movement device 40 configured as a portal system, that it can be moved relative to the circuit board in the direction of an X, Y and Z axis 42, 44, 46. The X axis is designated by the double arrow 42, wherein the Y axis is designated by the double arrow 44 and wherein the Z axis is designated by the double arrow 46. X, Y and Z axes 42, 44, 46 are understood to mean the axes of an axis system as customarily employed in machine tools and in which all axes are arranged orthogonal to one another. Advantageously, the X and Y axes 42, 44 are arranged parallel to the circuit board 14, so that a movement of the brush device 10 in the X-Y plane spanned by the X and Y axes 42, 44 leads to a shifting of the brush device 10 relative to the circuit board 14, wherein a separation in the direction of the Z axis 46 thereby remains unchanged. This separation in the direction of the Z axis 46 can be changed by a movement of the brush device 10 in the direction of the Z axis 46.

The portal system 40 has two Y-axis drives 48, one X-axis drive 50 as well as a Z-axis drive 52. The X-axis drive 50 is configured for moving the brush device 10 along the X axis 42. The Y-axis drive 48 is configured for moving the brush device 10 along the Y axis 44. In addition, the Z-axis drive 52 is configured for moving the brush device 10 along the Z axis 46. The axis drive 48, 50, 52 configured as linear drives are consequently arranged to be movable with respect to one another, so that movement of the Y-axis drive 48 leads to a shifting of the X-axis drive 50 and of the Z-axis drive 52 arranged on the X-axis drive 50 in the direction of the Y axis 44, wherein a movement of the X-axis drive 50 leads to a shifting of the Z-axis drive 52, arranged on the X-axis drive 50, in the direction of the X axis 42.

Through the use of a portal system 40, it is conceivable to build the device 12 into an already existing soldering system for a selective wave soldering process with a separate portal system 40. It is also conceivable, however, to install the brush device 10 into a soldering system for a selective wave soldering process which has two separate movable solder nozzles, wherein the brush device 10 is provided in place of a second solder nozzle.

In order to be able to position the brush 28 relative to the circuit board 14, respectively to the contact pins 20 inserted through the circuit board 14, even with cramped conditions on the underside 22 of the circuit board 14, and thus allow reliable removal of solder pearls and/or solder balls 24, an angle adjusting device 54 with an electrical adjustment motor is provided, which is configured for adjusting a processing angle of the brush device 10 in the range of approximately 0° to approximately 20° to the Z axis 46 in the direction of the double arrow 56. In this case, a processing angle is understood to be an angle between the drive axis 26 of the brush device 10 and the Z axis of the movement device 40.

In operation, the brush 28 of the brush device 10 is automatically, under CNC control for example, moved along the contact pins 20 by means of the portal system 40, so that solder pearls and/or solder balls 24 can be removed from the underside 22 of the circuit board 14.

Overall, a facility can be achieved with the soldering device 12 by which a simple, safe and automated removal of solder pearls and/or solder balls 24 from an underside 22 of a circuit board 14 can be made possible.

1. A soldering device with a brush device for removing solder pearls and/or solder balls from the circuit board, whereby the brush device has a brush that can be driven around a drive axis, and that is configured for removing solder pearls and/or solder balls, whereby a movement device is provided, whereby the brush device is arranged on the movement device so that it can be moved relative to the circuit board in the orthogonally to one another arranged direction of an X, Y or Z axis,
characterized in that the brush device is arranged below the circuit board in such a manner that solder pearls and/or solder balls are removed from the underside of the circuit board, and in that an angle adjusting device is provided which is configured for adjusting a processing angle of the brush device in the range of approximately 0° to approximately 20° to the Z axis.

2. The soldering device according to claim 1, wherein the movement device is a portal system.

3. The soldering device according to claim 2, wherein the portal system has at least one X-axis drive, configured for moving the brush device along the X axis, wherein the portal system has at least one Y-axis drive, which is configured for moving the brush device along the Y axis and wherein the portal system has at least one Z-axis drive which is configured for moving the brush device along the Z axis.

4. The soldering device according to claim 3 wherein the axis drives are configured as linear drives, particularly as chain drives, screw drives, ball screw drives, roller screw drives, direct linear drives, hydraulic cylinders or/or pneumatic cylinders.

5. The soldering device according to claim 1, wherein the movement device is a manipulator of a robot.

6. The soldering device according to claim 1, wherein the brush device has a brush drive, which is configured for generating an oscillating rotating movement of the brush.

7. The soldering device according to claim 1, wherein the brush device is configured for draining electrostatic discharges.

8. The soldering device according to claim 1, wherein the brush has electrically conducting bristles.

9. The soldering device according to claim 1, wherein the brush is electrically connected to a ground connection of the soldering device.

10. The soldering device according to claim 1, wherein the brush has a brush surface arranged orthogonally to the drive axis, wherein the brush surface is circular or ring-shaped.

11. (canceled)

12. The soldering device according to claim 1, wherein the angle adjustment device includes at least one electrical adjustment motor.

13. The soldering device according to claim 1, wherein a collecting bin is provided, which is configured for collecting solder pearls and/or solder balls removed from the underside of the circuit board.

14. The soldering device according to claim 12, wherein a suction device is provided which is configured for generating a reduced pressure in the collecting bin.

15. A soldering system for a selective wave soldering process, including a soldering device with a brush device having a brush that can be driven around a drive axis, and that is configured for removing solder pearls and/or solder balls, whereby a movement device is provided, whereby the brush device is arranged on the movement device so that it can be moved relative to the circuit board in the orthogonally to one another arranged direction of an X, Y or Z axis.

16. (canceled)
